(19) United States
(12) Patent Application Publication
(10) Pub. No.: US 2011/0181354 A1
(43) Pub. Date: Jul. 28, 2011

(54) RECEPTION DEVICE AND ELECTRONIC DEVICE USING THE SAME

(75) Inventors: Takashi Umeda, Osaka (JP); Hiroaki Ozeki, Osaka (JP); Takeshi Fujii, Osaka (JP); Susumu Fukushima, Osaka (JP)

(73) Assignee: Panasonic Corporation, Osaka (JP)

(21) Appl. No.: 13/121,801

(22) PCT Filed: Sep. 29, 2009
(86) PCT No.: PCT/JP2009/004969

§ 371 Date: Mar. 30, 2011

(30) Foreign Application Priority Data
Sep. 30, 2008 (JP) 2008-253115

(51) Int. Cl. H03G 3/20

(52) U.S. Cl. 330/129

(57) ABSTRACT

A reception device according to the present invention includes: a step-variable gain amplifier; and a controller operable to control the gain of the step-variable gain amplifier based on the signal quality value of a demodulator. The gain of the step-variable gain amplifier varies within N gains from a first gain to an N-th gain, and the controller changes a number of the gain one by one when changing the gain of the step-variable gain amplifier. Thus, it is possible to realize a reception device using the step-variable gain amplifier requiring a low control voltage as compared to a continuously-variable gain amplifier.

### TECHNICAL FIELD

The present invention relates to a reception device capable of receiving an analog modulated or digitally modulated signal used for a television set for home use, a mobile telephone, an in-vehicle navigation system, and the like, as well as to an electronic device using the reception device.

### BACKGROUND ART

FIG. 17 is a configurational diagram of a conventional reception device that receives an analog modulated used for a television set for home use and the like. Referring to FIG. 17, conventional reception device 100 that receives an analog modulated signal is provided with continuously-variable gain amplifier 101, mixer 103, bandpass filter (hereinafter referred to as BPF) 104, demodulator 105, signal quality detector 106, and controller 107.

An analog modulated signal is inputted into continuously-variable gain amplifier 101, whose gain varies continuously. Mixer 103 is connected to an output side of continuously-variable gain amplifier 101, and a local signal generated by oscillator 102 is inputted to mixer 103. The analog modulated signal converted into a signal of an intermediate frequency by mixer 103 is inputted into BPF 104. Further, demodulator 105 is connected to an output side of BPF 104, and demodulates the analog modulated signal. Signal quality detector 106 detects an electrical power value of the analog modulated signal outputted from demodulator 105. Data of the electrical power value that has been detected by signal quality detector 106 is inputted into controller 107, which changes the gain of continuously-variable gain amplifier 101 based on the data of the electrical power value data.

Continuously-variable gain amplifier 101 is used in conventional reception device 100, in order to obtain a favorable image quality. However, a high voltage value on the order of 5 V is required in gain control of continuously-variable gain amplifier 101. This poses a problem that configuring continuously-variable gain amplifier 101 is difficult when obtaining a high voltage value becomes difficult with advanced semiconductor microfabrication.

As related art reference information that relates to the invention of the present application, Patent Literature 1 is known, for example.

### CITATION LIST

### Patent Literature

Patent Literature 1: Unexamined Japanese Patent Publication No. 2003-179830

### DISCLOSURE OF THE INVENTION

A reception device according to the present invention includes: a step-variable gain amplifier whose gain discretely varies; a demodulator operable to demodulate an analog modulated signal; a signal quality detector operable to perform power detection of an electrical power value of the analog modulated signal outputted from the demodulator; and a controller operable to control a gain of the step-variable gain amplifier based on the electrical power value detected by a signal quality detector. The gain of the step-variable gain amplifier varies within N gains from a first gain to an N-th gain (N is an integer no smaller than 3, and the gain increases as the number of the gain increases from the first gain to the N-th gain), and the controller changes a number of the gain one by one when changing the gain of the step-variable gain amplifier. As the step-variable gain amplifier requiring a low control voltage compared to a continuously-variable gain amplifier is used, it is possible to provide a reception device even when obtaining a high voltage value becomes difficult with advanced semiconductor microfabrication.

Further, in a case in which a gain variation of the step-variable gain amplifier is large, there is a problem of a noise occurring in a screen when receiving analog broadcasting. Accordingly, when changing the gain of the step-variable gain amplifier, it is possible to make the reception screen for the analog broadcasting favorable by changing the number of the gain one by one.

Moreover, in a case in which the gain variation of the step-variable gain amplifier is large, there is a problem of a noise occurring in the screen when receiving digital broadcasting of multilevel modulation at high information transmission rate. Accordingly, when changing the gain of the step-variable gain amplifier, it is possible to make the reception screen for the digital broadcasting of the multilevel modulation at high information transmission rate favorable by changing the number of the gain one by one.

### BRIEF DESCRIPTION OF THE DRAWINGS

FIG. 1 is a configurational diagram of a reception device according to Embodiment 1.

FIG. 2 is a chart showing control voltage vs gain characteristics of step-variable gain amplifier 2.

FIG. 3 is a chart showing an amplifier gain to an input level of an analog modulated signal in reception device 1.

FIG. 4 is a configurational diagram of a reception device according to Embodiment 2.

FIG. 5 is a chart showing control voltage vs gain characteristics of step-variable gain amplifiers when receiving an analog modulated signal.

FIG. 6 is a chart showing control voltage vs gain characteristics of the step-variable gain amplifiers when receiving digital broadcasting.

FIG. 7 is a chart showing control voltage vs gain characteristics of the step-variable gain amplifiers when receiving the digital broadcasting in multilevel modulation at a high information transmission rate.

FIG. 8 is a configurational diagram of a reception device according to Embodiment 3.

FIG. 9 is a chart showing control voltage vs gain characteristics of step-variable gain amplifiers in reception device 301.

FIG. 10 is a chart showing relation between an input level of a broadcasting signal and an S/N ratio of an output signal after demodulation by the reception device.

FIG. 11 is a chart showing a gain of each step-variable gain amplifier to an input level of a broadcasting signal in reception device 301, and total gain characteristics of the amplifiers.

FIG. 12 is a chart showing a method of controlling step-variable gain amplifier 2 shown in FIG. 1 in a case in which an input level of a received signal changes during reception of an analog modulated signal in a channel selection period and a video signal reception period after the channel selection.

FIG. 13 is a chart showing signal intensity of an analog modulated signal along time-line.

FIG. 14 is a chart showing a method of controlling step-variable gain amplifier 2 in a case in which an input level of a received signal changes during reception of an analog modulated signal either in a video signal reception period or in a synchronous signal reception period.

FIG. 15 is a configurational diagram of a reception device according to Embodiment 5.

FIG. 16A is a chart showing temporal variation in a gain of a step-variable gain amplifier when receiving an analog modulated signal.

FIG. 16B is a chart showing temporal variation in a gain of a step-variable gain amplifier when receiving a digitally modulated signal.

FIG. 17 is a configurational diagram of a conventional reception device that receives an analog modulated signal used for a television set for home use and the like.

### PREFERRED EMBODIMENTS FOR CARRYING OUT OF THE INVENTION

### Embodiment 1

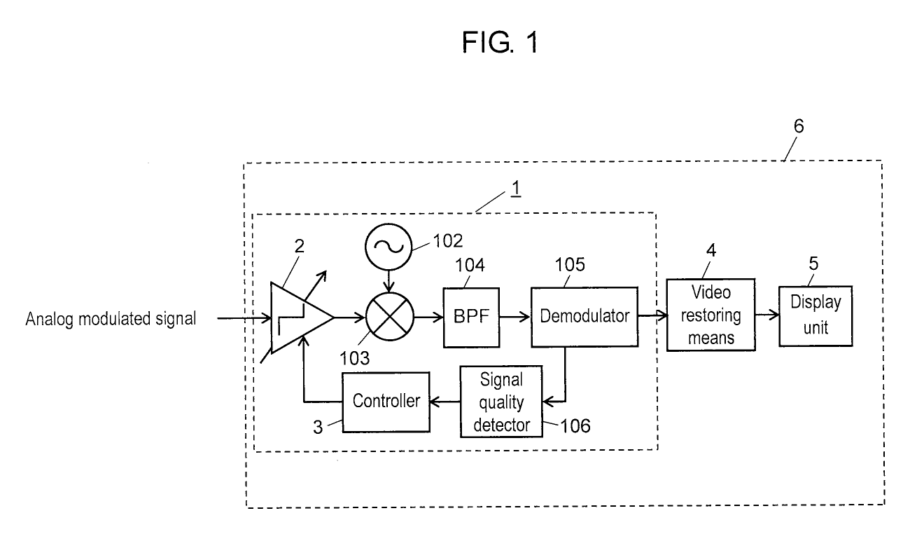

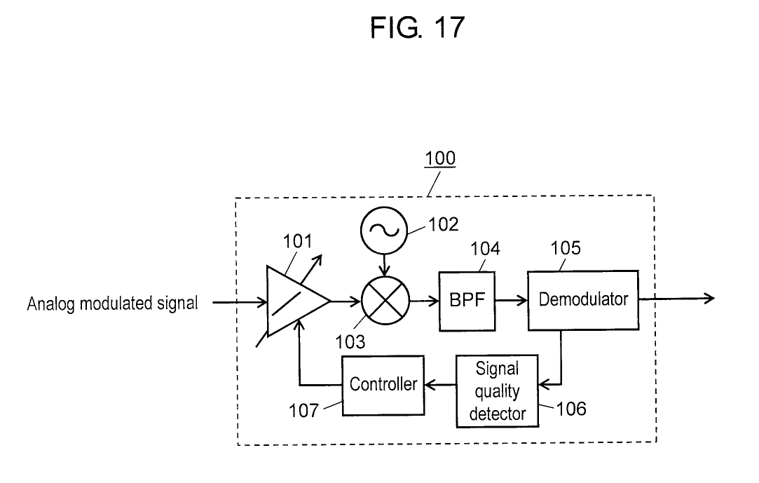

The following describes Embodiment 1 of the present invention with reference to the drawings. FIG. 1 is a configurational diagram of a reception device according to Embodiment 1. In order to simplify the description, like components are denoted by like reference numerals as shown in FIG. 17 of the conventional example.

Referring to FIG. 1, in reception device 1 according to Embodiment 1, an analog modulated signal is inputted into step-variable gain amplifier 2 whose gain discretely varies. The gain of step-variable gain amplifier 2 is controlled based on a gain control voltage from controller 3, and amplifies the inputted received signal. Then, the received signal is subjected to a frequency conversion into a signal of an intermediate frequency after being inputted into one input of mixer 103, and inputted into demodulator 105 via BPF 104. A local signal generated by oscillator 102 is inputted into the other input of mixer 103.

The received signal inputted into demodulator 105 is subjected to power detection by signal quality detector 106, and electrical power value data representing a signal quality value of the received signal is detected. The electrical power value data is inputted into controller 3. The gain of step-variable gain amplifier 2 is controlled based on the electrical power value data.

Analog broadcasting reception and display apparatus 6 can be configured by connecting video restoring means 4 and display unit 5 to an output of reception device 1, and whereby it is possible to provide an electronic device having superior reception characteristics.

An operation of step-variable gain amplifier 2 in reception device 1 thus configured is described in detail below.

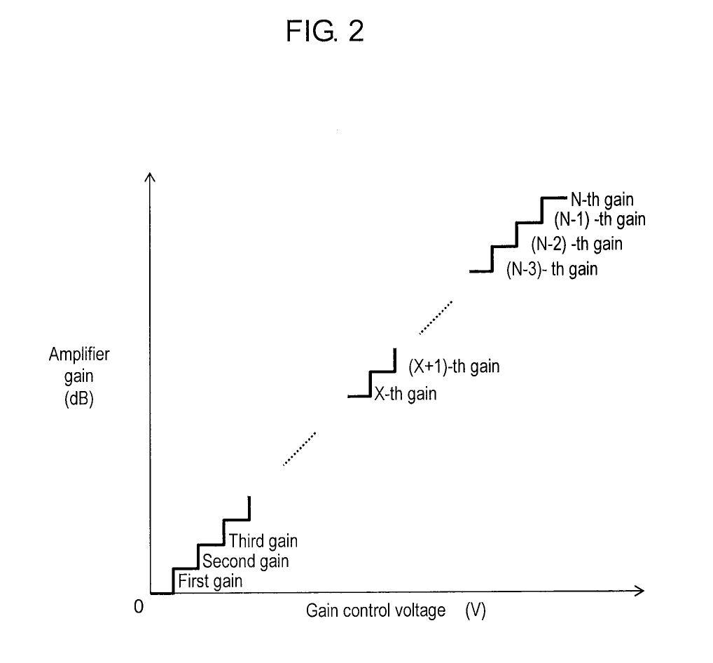

FIG. 2 is a chart showing control voltage vs gain characteristics of step-variable gain amplifier 2. The gain of step-variable gain amplifier 2 can vary along with a gain control voltage of controller 3, and is polarized such that an amplifier gain increases as the gain control voltage becomes greater (the gain increases as the number of the gain increases from a first gain to an N-th gain). Here, the amplifier gain of each gain control voltage has one of N gain values from the first gain to the N-th gain.

The N gain values are previously determined based on noise tolerance for a video signal after demodulation of the received signal and the signal quality value of the received signal (such as a signal-to-noise ratio or a received signal electrical power value, for example), and an operation is carried out such that the gain varies one by one based on the gain step.

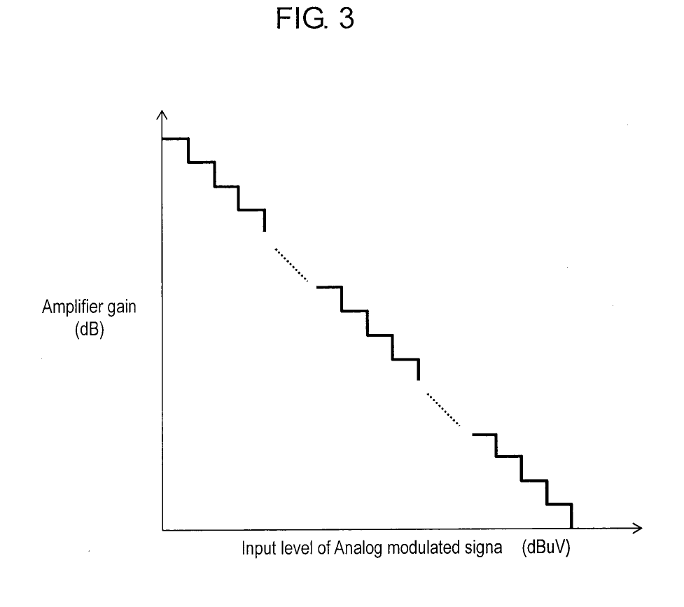

FIG. 3 is a chart showing the amplifier gain to an input level of the analog modulated signal in reception device 1. The gain of step-variable gain amplifier 2 is controlled based on the gain control voltage of controller 3 based on the electrical power value data detected by signal quality detector 106, so as to consistently obtain a constant demodulation output. At this time, controller 3 increments the gain of step-variable gain amplifier 2 one by one based on the gain step when the input level of the analog modulated signal changes to be smaller, and decrements the gain of step-variable gain amplifier 2 one by one based on the gain step when the input level of the analog modulated signal changes to be greater, so as to control the gain to be a required gain.

As the analog modulated signal has poor noise tolerance, if the gain variation of step-variable gain amplifier 2 is large, a noise occurs in a screen displayed in a display unit that displays the demodulated video signal. Accordingly, as it is possible to prevent the gain of step-variable gain amplifier 2 from varying in a short period of time by changing the number of the gain of step-variable gain amplifier 2 one by one without changing the number of the gain by more than one at a time, the analog modulated signal can be received in a favorable manner.

It should be noted that step-variable gain amplifier 2 has not been conventionally used in the reception by an analog television set. This is because the reception by the analog television set requires high sensitivity, and a variation range of the gain becomes wider when using step-variable gain amplifier 2, resulting in a noise in the screen. This is also attributed to the fact that the high voltage value required for a continuously-variable gain amplifier with smooth gain variation can be used in mobile terminals and the like. As such, step-variable gain amplifier 2 has been used only for the reception by a digital television set. This is because the reception sensitivity required for the digital television set is lower that that for the analog television set.

Reception device 1 according to the present invention employs step-variable gain amplifier 2 that has not been employed in the analog reception. Further, the reception device according to the present invention is provided with a function of changing the gain number one by one that is not provided for step-variable gain amplifier 2 that has been employed in a conventional digital television set.

With this, it is possible to realize step-variable gain amplifier 2 requiring a low voltage, as well as analog reception device 1 with high reception quality.

Further, by using a step-variable gain amplifier configured by combining attenuators of several types, it is possible to ensure high linearity of the circuits and a wide variable range of the gain, even when a voltage value of a core voltage is as low as 3.3 V or smaller with advanced semiconductor microfabrication, as compared to the conventional continuously-variable gain amplifier.

It should be noted that, values of such as a gain difference between an X-th gain and an (X-th)+1 gain (X is a given integer) and a time range of the gain variation among the N gain values are not required to be identical. With this, it is possible to converge an electrical power value of the demodulation output that momentarily changes into a predetermined demodulation output at high speed and with reduced noise. Specifically, if the electrical power value of the demodulation output is largely deviated from a predetermined value, it is possible to change the electrical power value of the demodulation output back to the predetermined value in a short period of time by either increasing the gain difference between the X-th gain and the (X-th)+1 gain (X is a given integer) or decreasing the time range of the gain variation in a range in which any noise occurs.

### Embodiment 2

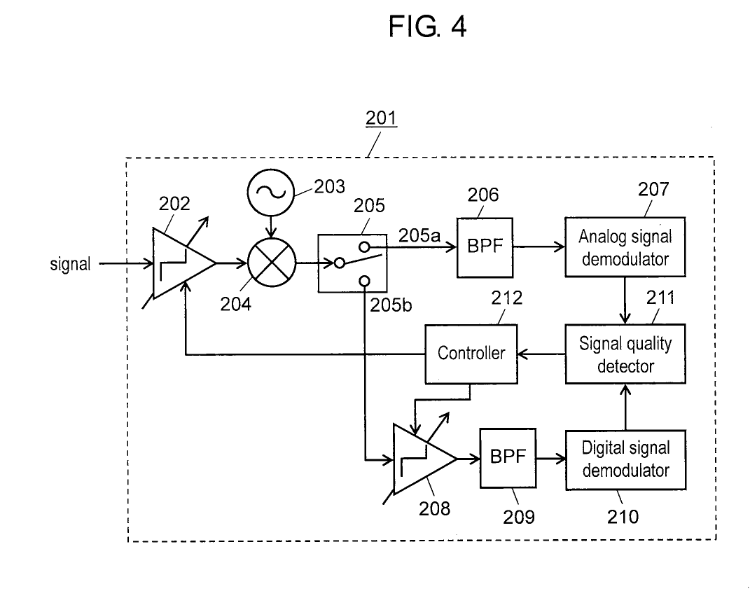

The following describes Embodiment 2 of the present invention with reference to the drawings. FIG. 4 is a configurational diagram of a reception device according to Embodiment 2.

Referring to FIG. 4, in reception device 201 according to Embodiment 2, a broadcasting signal is inputted into step-variable gain amplifier 202 whose gain discretely varies. A gain of step-variable gain amplifier 202 is controlled based on a gain control voltage from controller 212, and amplifies the inputted received signal. Then, the received signal is inputted into one input of mixer 204 and then subjected to a frequency conversion into a signal of an intermediate frequency, and inputted into switch 205. A local signal generated by oscillator 203 is inputted into the other input of mixer 204.

When receiving the analog broadcasting, switch 205 is connected to output terminal 205a, and the received signal is inputted, via BPF 206 that filters out the noise, into analog signal demodulator 207, which demodulates the analog modulated signal.

The received signal inputted into analog signal demodulator 207 is subjected to power detection by signal quality detector 211, and electrical power value data of the received signal is inputted into controller 212. Controller 212 controls the gain of step-variable gain amplifier 202 based on the electrical power value data, so as to obtain a constant demodulation output. When the input level of the analog modulated signal changes, controller 212 changes the gain of step-variable gain amplifier 202 one by one based on the gain step, so as to control the gain to be a required gain. With this, as it is possible to prevent the gain of step-variable gain amplifier 202 from varying in a short period of time, the analog broadcasting can be received in a favorable manner.

Here, signal quality detector 211 is a circuit block configured to detect a signal quality value, examples of which include a signal electrical power value, a signal-to-noise ratio (S/N), a C/N value, an error rate, or the like, representing the signal quality.

When receiving the digital broadcasting, switch 205 is connected to output terminal 205b, and the received signal is inputted into step-variable gain amplifier 208. A gain of step-variable gain amplifier 208 is controlled based on a gain control voltage from controller 212, and amplifies the inputted received signal. Then, the received signal is inputted into digital signal demodulator 210 via BPF 209, and the digitally modulated signal is demodulated.

The received signal inputted into digital signal demodulator 210 is subjected to power detection by signal quality detector 211, and electrical power value data of the received signal is inputted into controller 212. Controller 212 controls the gains of step-variable gain amplifier 202 and step-variable gain amplifier 208 based on the electrical power value data, so as to obtain a constant demodulation output. Specifically, when the input level of the digitally modulated signal changes, controller 212 changes the gains of step-variable gain amplifier 202 and step-variable gain amplifier 208 one by one based on their gain steps, respectively, so as to control the gains to be required gains.

A method of setting gain step widths of the step-variable gain amplifiers in reception device 201 thus configured is described in detail below.

Here, the gain step width refers to a gain difference between an X-th gain and an (X-th)+1 gain (X is a given integer) in a step-variable gain amplifier having a discrete gain.

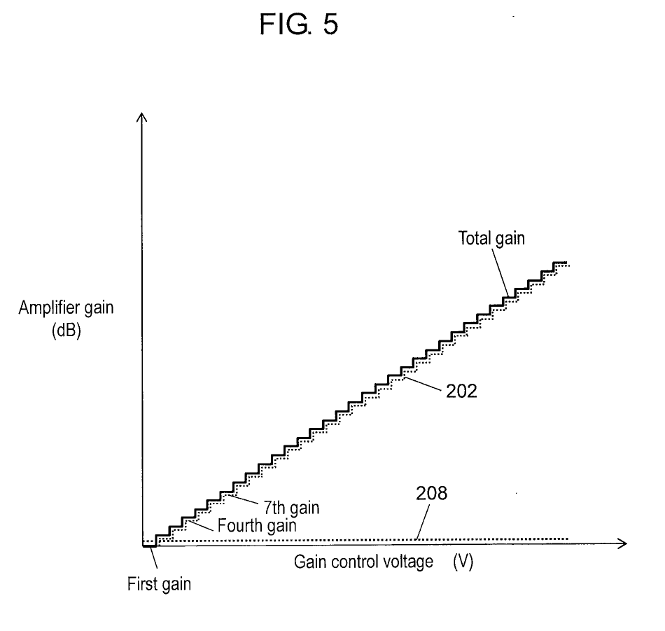

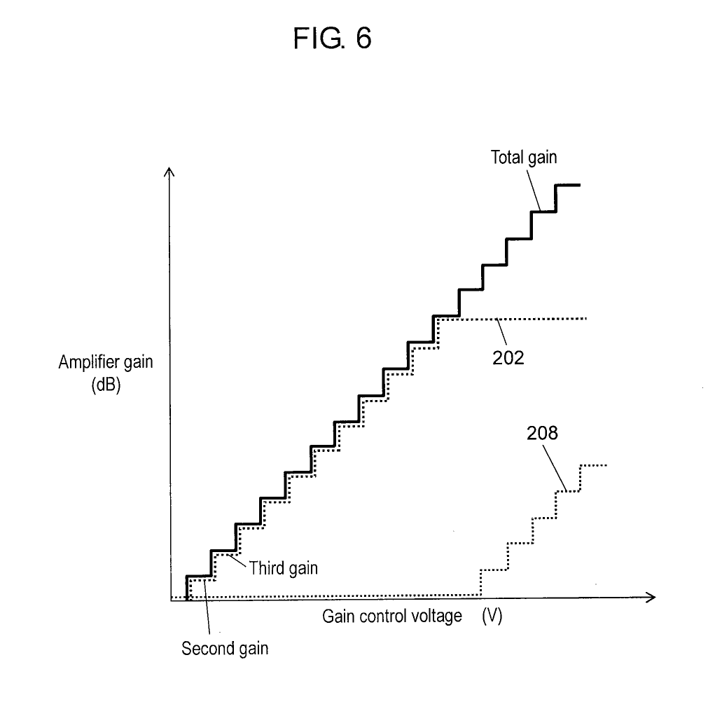

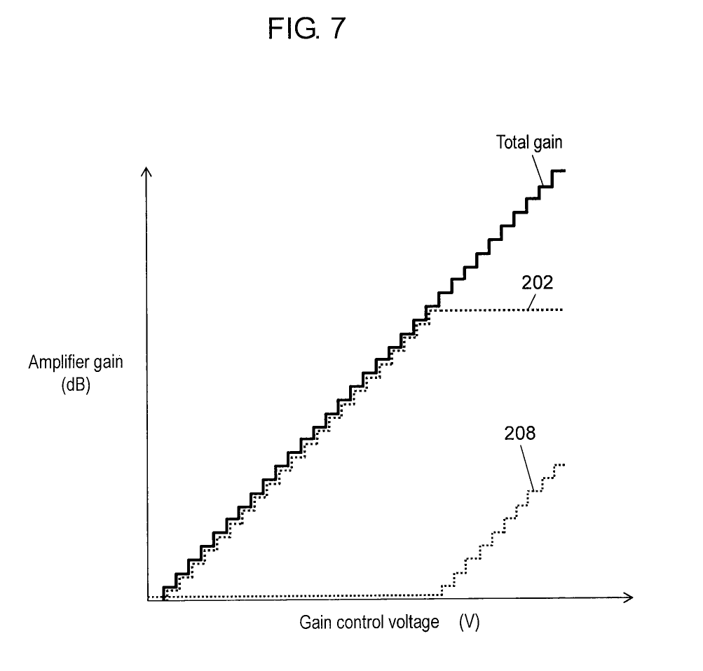

FIG. 5, FIG. 6, and FIG. 7 are charts each showing control voltage vs gain characteristics of step-variable gain amplifier 202 and step-variable gain amplifier 208 and total gain characteristics of the amplifiers in the corresponding broadcasting method.

FIG. 5 is the chart showing the control voltage vs gain characteristics of the step-variable gain amplifiers when receiving the analog modulated signal. When receiving the analog modulated signal, switch 205 is connected to output terminal 205a, and the gain of step-variable gain amplifier 202 varies within L discrete gain values from a first gain to an L-th gain. The L discrete gain values are previously determined based on noise tolerance for a video signal after demodulation of the received signal and the signal quality value of the received signal, and the operation is carried out such that the gain varies one by one based on the gain step (a gain step smaller than 0.3 dB, as an example).

Controller 212 increments the gain of step-variable gain amplifier 202 one by one based on the gain step when the input level of the analog modulated signal changes to be smaller, and decrements the gain of step-variable gain amplifier 202 one by one based on the gain step when the input level of the analog modulated signal changes to be greater, so as to control the gain to be a required gain.

As the analog modulated signal has poor noise tolerance compared to the digitally modulated signal, if the gain variation of step-variable gain amplifier 202 is large, a noise occurs in a screen displayed in a display unit that displays the demodulated video signal. Accordingly, as it is possible to prevent the gain of step-variable gain amplifier 202 from varying in a short period of time by changing the number of the gain of step-variable gain amplifier 202 one by one without changing the number of the gain by more than one at a time, the analog modulated signal can be received in a favorable manner.

Further, it is possible to change the gain step width based on a signal quality value other than the electrical power value of the analog modulated signal (corresponding to such as S/N, for example).

Specifically, as noise tolerance increases when the S/N of the received signal is large, the noise does not occur easily in the screen even when the gain step width is large. A first signal quality value and a second signal quality value that is superior to the first signal quality value are presumed as levels of the signal quality value. The gain step width when the signal quality value detected by signal quality detector 211 is the first signal quality value can be set to be smaller than the gain step width when the signal quality value is the second signal quality value.

With this, when the signal quality value of the received signal is the first signal quality value, the analog modulated signal can be received in a favorable manner. Further, when the signal quality value of the received signal is the second signal quality value, it is possible to decrease a convergence time until the gain of the step-variable gain amplifier becomes a predetermined gain if the input level of the received signal changes.

FIG. 6 is the chart showing the control voltage vs gain characteristics of the step-variable gain amplifiers when receiving the digital broadcasting. When receiving the digital broadcasting, switch 205 is connected to output terminal 205b, and a total gain obtained by adding the gain of step-variable gain amplifier 202 and the gain of step-variable gain amplifier 208 varies within M discrete gain values from a first gain to an M-th gain.

As the digitally modulated signal has superior noise tolerance compared to the analog modulated signal, it is possible to receive the signal in a favorable manner even if the gain step widths of step-variable gain amplifiers 202 and 208 are increased. As such, by setting the gain step width when receiving the digitally modulated signal (see FIG. 6) to be larger than the gain step width when receiving the analog modulated signal (see FIG. 5), it is possible to decrease the convergence time until the gains of step-variable gain amplifiers 202 and 208 become the predetermined gain when the input level of the received signal changes (the gain step width on the order of 2 dB as one example, although this depends on the broadcasting method).

Thus, the gain step width of step-variable gain amplifier 208 through which only the digitally modulated signal passes in FIG. 4 can be set to be larger. With this, it is possible to keep a circuit scale of step-variable gain amplifier 208 smaller. In addition, the gain step width of step-variable gain amplifier 202 through which both of the analog modulated signal and the digitally modulated signal pass in FIG. 4 can be set to be smaller than that of step-variable gain amplifier 208 such that no noise occurs when demodulating the analog modulated signal. With this, it is possible to make the reception characteristics of reception device 201 favorable, while minimizing the circuit scale of reception device 201.

Further, the gain step width of step-variable gain amplifier 202 when receiving the analog modulated signal (see FIG. 5) is different from the gain step width of step-variable gain amplifier 202 when receiving the digitally modulated signal (see FIG. 6). These characteristics can be realized by single step-variable gain amplifier 202. Specifically, a fourth gain in the gain of step-variable gain amplifier 202 when receiving the analog modulated signal (see FIG. 5) is used as a second gain in the gain of step-variable gain amplifier 202 when receiving the digitally modulated signal (see FIG. 6). Similarly, a seventh gain in the gain of step-variable gain amplifier 202 when receiving the analog modulated signal (see FIG. 5) is used as a third gain in the gain of step-variable gain amplifier 202 when receiving the digitally modulated signal (see FIG. 6). With this, it is possible to realize step-variable gain amplifier 202 having two profiles only with single step-variable gain amplifier 202 without increasing the circuit scale.

FIG. 7 is the chart showing the control voltage vs gain characteristics of the step-variable gain amplifiers when receiving the digital broadcasting in multilevel modulation at a high information transmission rate. A required C/N representing noise tolerance of the digitally modulated signal varies depending on the modulation method, and the noise tolerance becomes low as an amount of transmitted information increases. Therefore, by setting the gain step width to be small, it is possible to receive the digital broadcasting in multilevel modulation at a high information transmission rate in a favorable manner.

Further, the noise tolerance represented by the required C/N also varies depending on such as an error correcting capability of an error correcting circuit (not depicted) included in a demodulation unit and reception environment such as mobile reception, in addition to the modulation method. Therefore, it is possible to determine the gain step width and the gain variation range per unit time considering such as the error correcting capability and the reception environment. The gain step width and the gain variation range per unit time can be previously determined, or can be adjusted by controller 212 as needed based on the signal quality value detected by signal quality detector 211.

For example, appropriate initial values of the gain step width and the gain variation range per unit time can be determined based on previously known information such as the modulation method and the error correcting capability, and then fine adjustment can be performed to the gain step width and the gain variation range per unit time based on the signal quality value with reference to the initial values. With this, it is possible to realize a reception device with less error while adapting to the reception environment that momentarily changes. Further, it is possible to prepare a plurality of initial values of the gain step width and the gain variation range per unit time according to the modulation methods and the like, and to select the initial values depending on the received digital modulation signal. With this, it is possible to provide a best suited gain profile for the reception of various digital modulation signals by a step-variable gain amplifier with a reduced circuit scale.

As described above, switch 205 is provided in order to select a circuit of a subsequent stage without fail when receiving the digital broadcasting and when receiving the analog broadcasting. However, switch 205 is not necessarily required as long as the performance is ensured. For example, instead of providing switch 205, it is possible to directly connect the output of mixer 204 to BPF 206 and step-variable gain amplifier 208. In this case, when receiving the analog modulation signal, it is presumable that the reception performance deteriorates due to an influence of input impedance of step-variable gain amplifier 208. However, when receiving the analog broadcasting, it is possible to decrease the influence to the reception of the analog modulation signal by controlling the gain to be a predetermined gain with which the input impedance of step-variable gain amplifier 208 becomes high.

Here, when receiving the digitally modulated signal, the connection of switch 205 in FIG. 4 can be switched over from 205a to 205b only during a guard interval period or the like in which the reception quality is not largely influenced. The signal quality value of the signal between mixer 204 and step-variable gain amplifier 208 is derived by signal quality detector 211. With this, electrical power values of an interfering wave and a desired wave can be grasped, and accordingly it is possible to effectively control the gains of step-variable gain amplifiers 202 and 208, and to realize a reception device with high reception quality. Further, as described above, when switch 205 is not provided, the signal quality value of the signal between mixer 204 and step-variable gain amplifier 208 can be derived consistently. Using this, it is possible to effectively control the gains of step-variable gain amplifiers 202 and 208. Here, in the above case, when the detection of the interfering wave by BPF 206 cannot be carried out in a favorable manner, it is possible to additionally provide a path through which an input to signal quality detector 211 is possible without passing through BPF 206. Specifically, for example, it is possible to provide switch 205 with a further output terminal, and connect this output terminal with signal quality detector 211 by switching over, or it is possible to additionally provide a bypassing path with a switch through which the connection to the analog signal demodulator 207 without passing through BPF 206 is possible.

Further, in order to reduce the power consumption, it is possible to stop the functions of step-variable gain amplifier 208 and digital signal demodulator 210 when receiving the analog modulated signal, and it is possible to stop the function of analog signal demodulator 207 when receiving the digitally modulated signal.

It should be noted that, although step-variable gain amplifier 208 is used only when receiving the digitally modulated signal in FIG. 4, the present embodiment is not limited to this example, and the number of the amplifiers can be increased or decreased according to the gain required for the reception. For example, step-variable gain amplifier 208 can be inserted when receiving the analog modulated signal.

Further, while the gain varies in stepwise manner only for step-variable gain amplifier 202 when receiving the analog modulated signal (see FIG. 5), and the gain varies in stepwise manner for the two of step-variable gain amplifiers 202 and 208 when receiving the digitally modulated signal (see FIG. 7), the present embodiment is not limited to this example. In FIG. 4 to FIG. 7, it is presumed to use the reception device capable of receiving the analog broadcasting and the digital broadcasting, and the gain range of the amplifier required when receiving the analog broadcasting is narrower than the gain range of the amplifier required when receiving the digital broadcasting. As a result, the configuration of the circuit block shown in FIG. 4 and the characteristics shown in FIG. 5 to FIG. 7 are shown. Specifically, the analog broadcasting reception is supported by the gain range of step-variable gain amplifier 202, and the range width that is insufficient for the reception of the digital broadcasting is supported by additionally providing step-variable gain amplifier 208.

Further, it is possible to provide a configuration in which digital signal demodulator 210 includes a fading level detector (not depicted), and to input at least a part of the digitally modulated signal that has been inputted to digital signal demodulator 210. The fading level detector has a function of detecting a level of the fading of the inputted digitally modulated signal.

Here, the fading occurs due to reflection of a radiowave against an obstacle above the ground, an ionized layer in the atmosphere, or the like, or movement of a transceiving terminal itself in mobile telecommunications, and refers to the phenomenon in which a plurality of signals that have arrived at the receiving antenna with time differences intensify or attenuates each other when the signals are synthesized and the signal level temporally changes along the frequency scale. The fading level is an index that represents the magnitude of a temporal power change of the received signal along the frequency scale.

Specific examples how the fading level detector detects the fading level include a method of estimating a Doppler frequency from the deviation of a carrier frequency of the received signal, deriving a moving speed of the reception device from the Doppler frequency, and estimating the fading level from the moving speed.

In the configuration in which digital signal demodulator 210 includes the fading level detector, when inputting the digitally modulated signal, the gain step width of step-variable gain amplifier 208 can be changed by the controller based on the fading level signal outputted by the fading level detector. Specifically, it is possible that the gain step width of step-variable gain amplifier 208 becomes smaller when the fading level is high (when the temporal change of the signal level along the frequency scale is large), and the gain step width of step-variable gain amplifier 208 becomes larger when the fading level is low. With this, it is possible to select a best suited gain step width of step-variable gain amplifier 208 according to the fading level, and it is possible to realize a reception device with superior reception characteristics under the fading environment.

### Embodiment 3

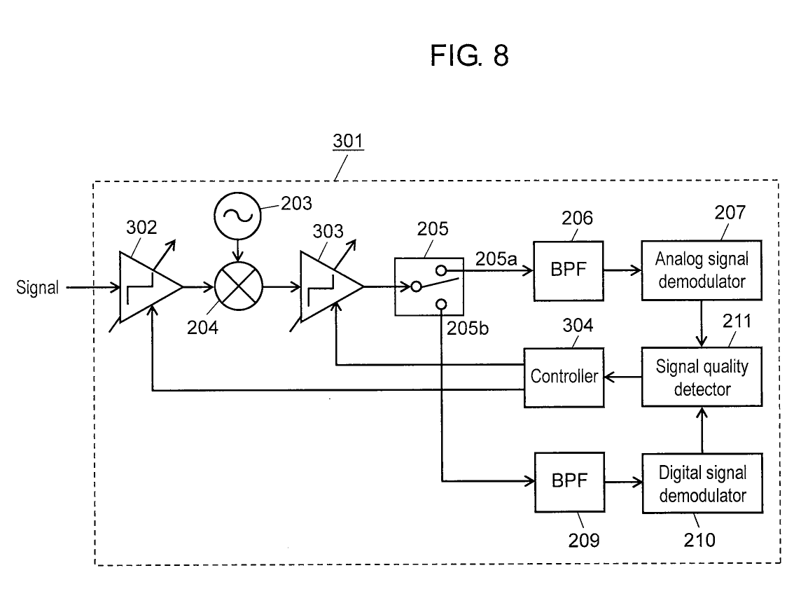

The following describes Embodiment 3 of the present invention with reference to the drawings. FIG. 8 is a configurational diagram of a reception device according to Embodiment 3. In order to simplify the description, like components are denoted by like reference numerals as shown in FIG. 4 of Embodiment 2.

Referring to FIG. 8, in reception device 301 according to Embodiment 3, a broadcasting signal is inputted, for example, into first step-variable gain amplifier 302 whose gain discretely varies. A gain of first step-variable gain amplifier 302 is controlled based on a gain control voltage from controller 304, and amplifies the inputted received signal.

Then, the received signal is inputted into one input of mixer 204, and is subjected to a frequency conversion into a signal of an intermediate frequency. A local signal generated by oscillator 203 is inputted into the other input of mixer 204. The received signal converted into the signal of the intermediate frequency by mixer 204 is inputted into second step-variable gain amplifier 303. A gain of second step-variable gain amplifier 303 is controlled based on a gain control voltage from controller 304, and the received signal is inputted into switch 205 via second step-variable gain amplifier 303.

When receiving the analog broadcasting, switch 205 is connected to output terminal 205a, the received signal is inputted to analog signal demodulator 207 via BPF 206, and the analog modulated signal is demodulated.

The received signal inputted into analog signal demodulator 207 is subjected to power detection by signal quality detector 211, and electrical power value data of the received signal is inputted into controller 304. Controller 304 controls the gains of first step-variable gain amplifier 302 and second step-variable gain amplifier 303 based on the electrical power value data, so as to obtain a constant demodulation output. When the input level of the analog modulated signal changes, controller 304 changes the gains of first step-variable gain amplifier 302 and second step-variable gain amplifier 303 one by one based on the gain step, so as to control the gains to be a required gain.

Here, signal quality detector 211 is a circuit block configured to detect a signal quality value, examples of which include a signal electrical power value, a signal-to-noise ratio (S/N), or the like.

When receiving the digital broadcasting, switch 205 is connected to output terminal 205b, the received signal is inputted into digital signal demodulator 210 via BPF 209, and the digitally modulated signal is demodulated.

The received signal inputted into digital signal demodulator 210 is subjected to power detection by signal quality detector 211, and electrical power value data of the received signal is inputted into controller 304. Controller 304 controls the gains of first step-variable gain amplifier 302 and second step-variable gain amplifier 303 based on the electrical power value data, so as to obtain a constant demodulation output. When the input level of the digitally modulated signal changes, the amplifier gains are controlled to be required gains by changing one by one based on their gain steps.

Here, signal quality detector 211 is a circuit block configured to detect a signal quality value, examples of which include a signal electrical power value, a C/N value, an error rate, or the like.

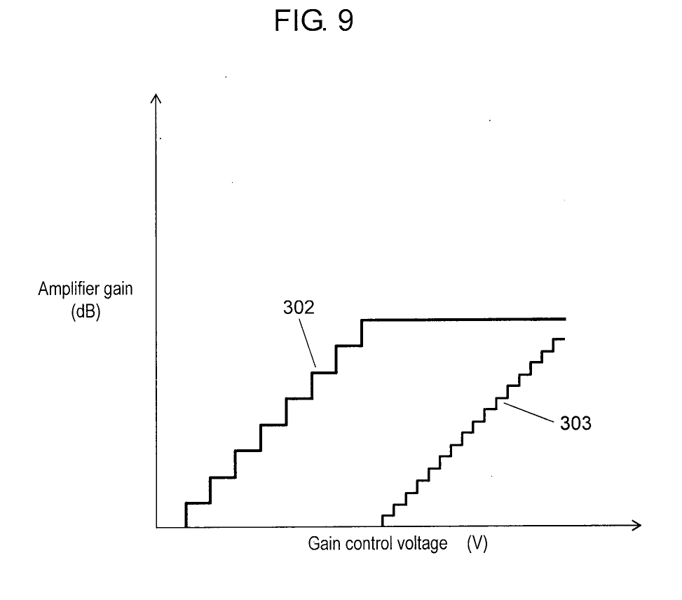

A method of setting gain step widths of first step-variable gain amplifier 302 and second step-variable gain amplifier 303 in reception device 301 thus configured is described in detail below with reference to FIG. 9 to FIG. 11.

FIG. 9 is a chart showing control voltage vs gain characteristics of a step-variable gain amplifier in reception device 301. The gain of first step-variable gain amplifier 302 can vary along with a gain control voltage of controller 304, and is polarized such that the amplifier gain increases as the gain control voltage becomes greater (the gain increases as the number of the gain increases from a first gain to an N-th gain).

Here, the amplifier gain of each gain control voltage has one of the number N of gain values from the first to N-th. Further, the gain of second step-variable gain amplifier 303 can vary along with the gain control voltage of controller 304, and is polarized such that an amplifier gain increases as the gain control voltage becomes greater (the gain increases as the number of the gain increases from a first gain to an n-th gain). Here, the amplifier gain of each gain control voltage has one of the number n of gain values from the first gain to the n-th gain.

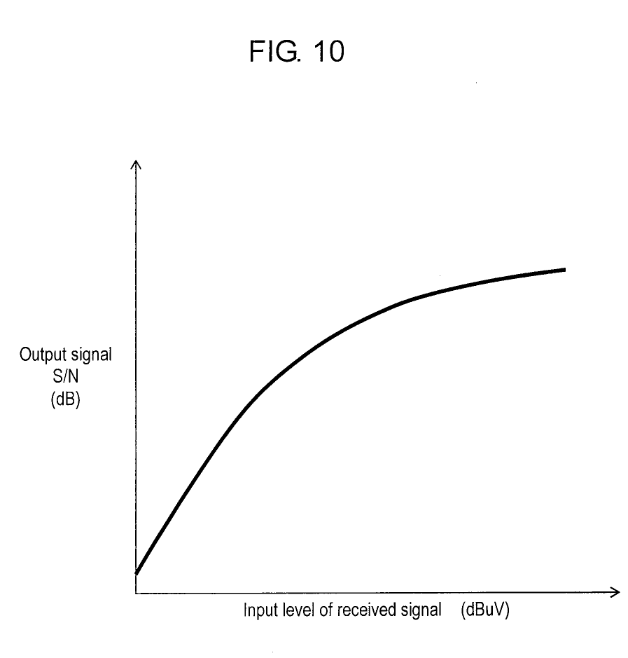

FIG. 10 is a chart showing relation between an input level of the broadcasting signal and the S/N ratio of the output signal after the demodulation by the reception device. As the input level of the broadcasting signal becomes high, a signal level ratio to noise improves and the S/N increases. When the input level of the broadcasting signal is low, the S/N decreases and the noise tolerance decreases. When the input level of the broadcasting is high, the S/N increases and the noise tolerance increases.

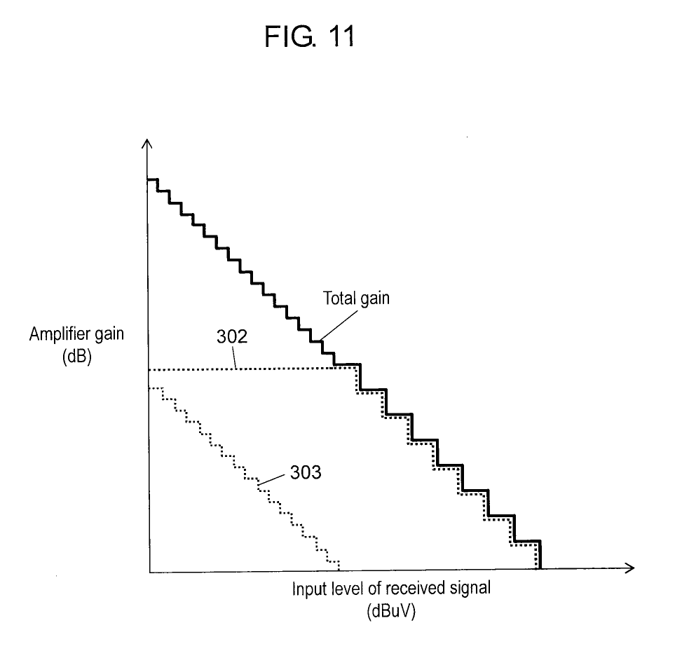

FIG. 11 is a chart showing the gain of each step-variable gain amplifier to the input level of the broadcasting signal in reception device 301, and the total gain characteristics of the amplifiers.

In this manner, in an area in which the input level of broadcasting signal is low compared to an area in which the input level of the broadcasting signal is high, the gain step width of second step-variable gain amplifier 303 that preferentially operates is set to be small. With this, it is possible to receive the broadcasting signal in a favorable manner in an area in which the noise tolerance is poor. In other words, in the area in which the input level of the broadcasting signal is low, the gain of second step-variable gain amplifier 303 that is an amplifier of a subsequent stage having less influence to NF characteristics is preferentially changed. Further, in the area in which the input level of the broadcasting signal is high, the gain step width is set to be smaller than the gain step width of first step-variable gain amplifier 302 that is preferentially changed.

On the other hand, in the area in which the input level of the broadcasting signal is high, the gain step width of first step-variable gain amplifier 302 that preferentially operates is set to be larger than that of second step-variable gain amplifier 303. With this, a convergence time until the gain of the step-variable gain amplifier reaches a predetermined gain can be shortened. Further, it is possible to reduce the circuit scale of step-variable gain amplifier 302 by setting the step width to be large.

It should be noted that a large number of amplifiers including second step-variable gain amplifier 303 can be provided on the subsequent stage of first step-variable gain amplifier 302. It is sufficient at least one of these amplifiers is designed to have the gain step width smaller than a gain step width of first step-variable gain amplifier 302.

Further, the step-variable gain amplifier to be controlled can be changed based on the signal quality value of the received signal (for example, BER, C/N, or the like). When in a first area in which the signal quality value of the received signal is poor, it is possible to receive the broadcasting signal in a favorable manner by controlling second step-variable gain amplifier 303. Further, when in a second area in which the signal quality value of the received signal is superior than that in the first area, it is possible to shorten the convergence time until the gain of the step-variable gain amplifier reaches the predetermined gain by controlling the gain of first step-variable gain amplifier 302. Further, it is also possible to reduce the circuit scale of first step-variable gain amplifier 302 by setting the gain step width to be large.

### Embodiment 4

The following describes Embodiment 4 of the present invention with reference to the drawings. A basic configurational diagram of a reception device according to Embodiment 4 is the same as that shown in FIG. 1, which is the configurational diagram of the reception device according to Embodiment 1. In addition, basic control voltage vs gain characteristics of step-variable gain amplifier 2 according to Embodiment 4 is the same as that shown in FIG. 2 for Embodiment 1. As FIG. 1 and FIG. 2 have been described in Embodiment 1, the description is not given here.

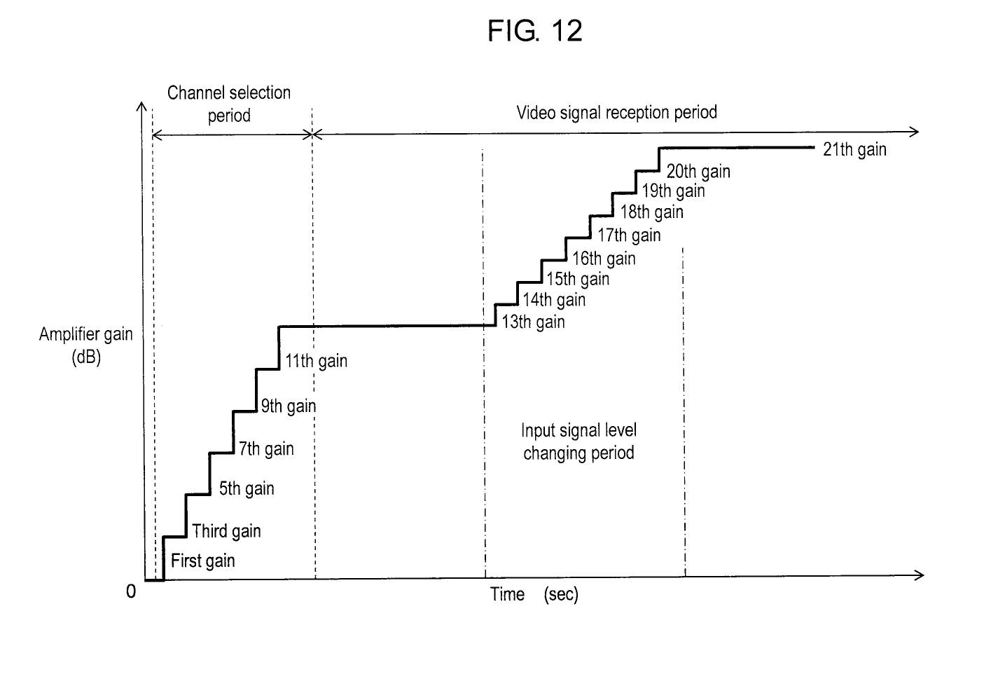

FIG. 12 is a chart showing a method of controlling step-variable gain amplifier 2 shown in FIG. 1 in a case in which an input level of a received signal changes during reception of an analog modulated signal in a channel selection period and a video signal reception period after the channel selection. When it is presumed that an initial value of the amplifier gain is a first gain and a required gain after the channel selection is a thirteenth gain in step-variable gain amplifier 2 having the control voltage vs gain characteristics shown in FIG. 2, it is controlled to change the number of the gain of step-variable gain amplifier 2 by more than one as shown in FIG. 12.

As it is not necessary to display the video signals during the channel selection period when receiving the analog broadcasting, and a required suppressing value for noise occurring due to the gain that varies in a stepwise manner is low, it is possible to increase the gain step width of step-variable gain amplifier 2. With this, by controlling the number of the gain so as to be changed by more than one, it is possible to shorten the convergence time until the gain of step-variable gain amplifier 2 reaches the predetermined gain. It should be noted that the broadcasting signal is not necessarily limited to the analog broadcasting, and it is possible to obtain the same effect when receiving the digitally modulated signal.

When the input level of the received signal changes during the video signal reception period after the channel selection, and the required gain becomes a twenty-first gain, the number of the gain of step-variable gain amplifier 2 is controlled so as to change one by one as shown in FIG. 12. As the analog modulated signal has poor noise tolerance, if the gain variation of step-variable gain amplifier 2 is large, a noise occurs in a screen displayed in a display unit that displays the demodulated video signal. Accordingly, it is possible to reduce the gain variation of step-variable gain amplifier 2 by changing the number of the gain one by one, and to receive the analog broadcasting in a favorable manner.

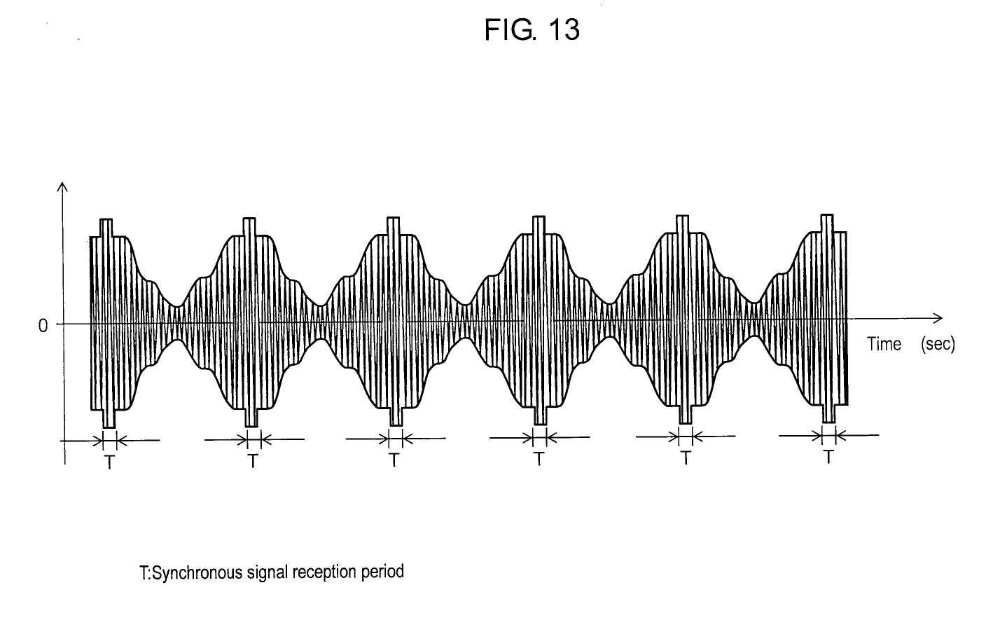

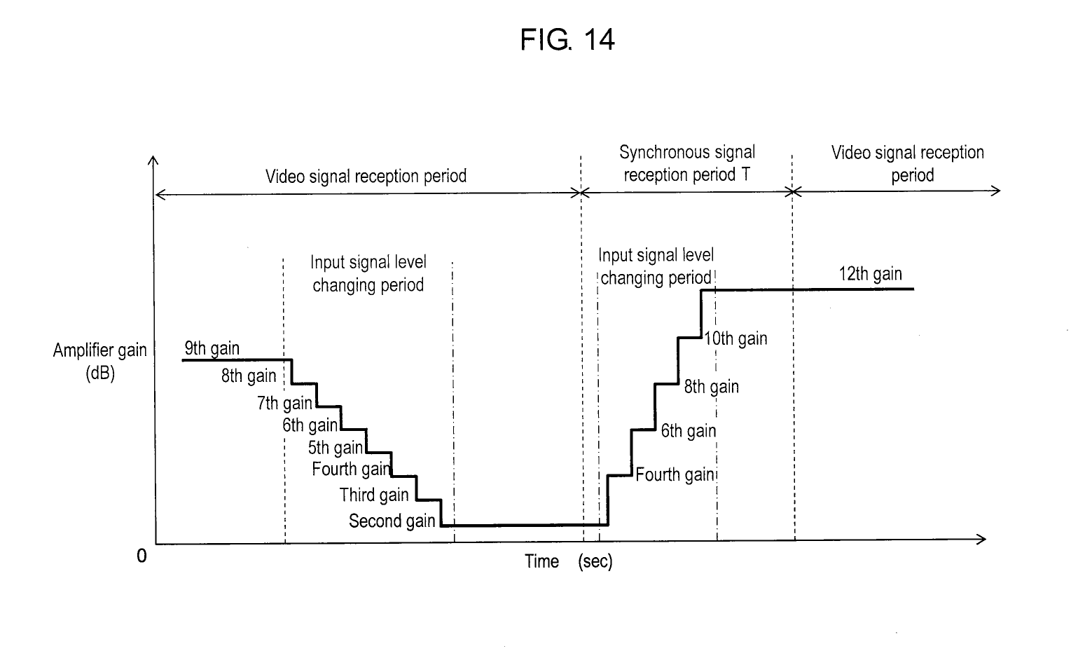

Next, a method of controlling the gain of step-variable gain amplifier 2 when receiving a synchronous signal in the analog broadcasting is described with reference to FIG. 13 and FIG. 14.

FIG. 13 is a chart showing signal intensity of the analog modulated signal along time-line. Referring to FIG. 13, a synchronous signal included in a synchronous signal reception period T is a switching signal for shifting between horizontal scanning in the screen.

FIG. 14 is a chart showing a method of controlling step-variable gain amplifier 2 in a case in which the input level of the received signal changes during the reception of the analog modulated signal either in a video signal reception period or in a synchronous signal reception period.

In the video signal reception period, when it is presumed that the initial value of the amplifier gain is a ninth gain, and the required value of the amplifier gain after the change of the input signal level is the second gain, it is controlled so as to change the number of the gain of step-variable gain amplifier 2 one by one as shown in FIG. 14. As the analog modulated signal has poor noise tolerance, if the gain variation of step-variable gain amplifier 2 is large, a noise occurs in a screen displayed in a display unit that displays the demodulated video signal. Accordingly, it is possible to reduce the gain variation per unit time of step-variable gain amplifier 2 by changing the number of the gain one by one, and to receive the analog broadcasting in a favorable manner per unit time.

On the other hand, during the synchronous signal reception period, when it is presumed that the initial value of the amplifier gain is the second gain, and the required value of the amplifier gain after the change of the input signal level is a twelfth gain, it is controlled so as to change the number of the gain of step-variable gain amplifier 2 by more than one as shown in FIG. 14.

As it is not necessary to display the video signals during the synchronous signal period, and a required suppressing value for noise occurring due to the gain that varies in a stepwise manner is low, it is possible to increase the gain step width of step-variable gain amplifier 2. Therefore, by controlling the number of the gain so as to be changed by more than one, it is possible to shorten the convergence time until the gain of step-variable gain amplifier 2 reaches the predetermined gain.

It should be noted that, even during the synchronous period, there is a case in which it is controlled to change the number of the gain one by one if a value of the power change in the input signal level is small.

### Embodiment 5

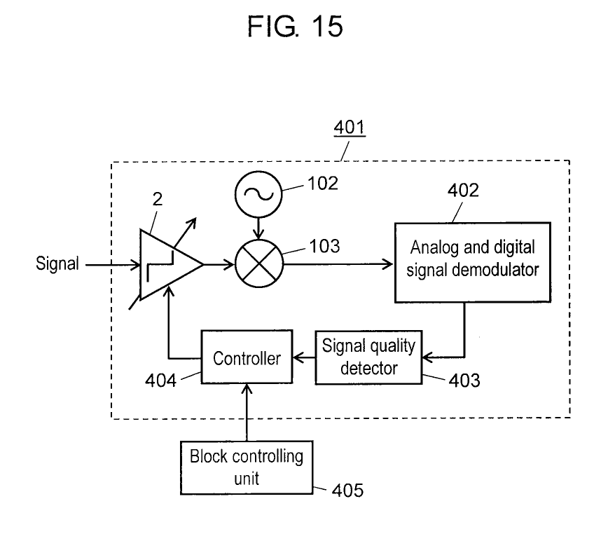

The following describes Embodiment 5 of the present invention with reference to the drawings. FIG. 15 is a configurational diagram of a reception device according to Embodiment 5. In order to simplify the description, like components are denoted by like reference numerals as shown in FIG. 1 of Embodiment 1.

Referring to FIG. 15, in reception device 401 according to Embodiment 5, an analog modulated signal and a digitally modulated signal are inputted into step-variable gain amplifier 2 whose gain discretely varies. A gain of step-variable gain amplifier 2 is controlled based on a gain control voltage from controller 404, and amplifies the received signal inputted into step-variable gain amplifier 2.

Then, the received signal is subjected to a frequency conversion into a signal of an intermediate frequency after being inputted into one input of mixer 103, and inputted into analog and digital signal demodulator 402. A local signal generated by oscillator 102 is inputted into the other input of mixer 103.

The received signal inputted into analog and digital signal demodulator 402 is subjected to power detection by signal quality detector 403, and electrical power value data of the received signal is inputted into controller 404. The gain of step-variable gain amplifier 2 is controlled based on the electrical power value data.

Information of the received signal is inputted from block controlling unit 405 to controller 404, and an amplifier control voltage outputted from controller 404 is appropriately controlled depending on the type of the signal, that is, the analog modulated signal or the digitally modulated signal.

Here, analog and digital signal demodulator 402 includes a demodulating function for the analog broadcasting and the digital broadcasting. In addition, a channel selection BPF for the analog broadcasting and the digital broadcasting are included in the demodulator. It should be noted that the channel selection BPF is not necessarily required to be included in the demodulator, and can be configured by a passive component such as a SAW (Surface Acoustic Wave) filter. Signal quality detector 403 detects power of at least one of the analog modulated signal and the digitally modulated signal that has been received, and the electrical power value data is inputted into controller 404.

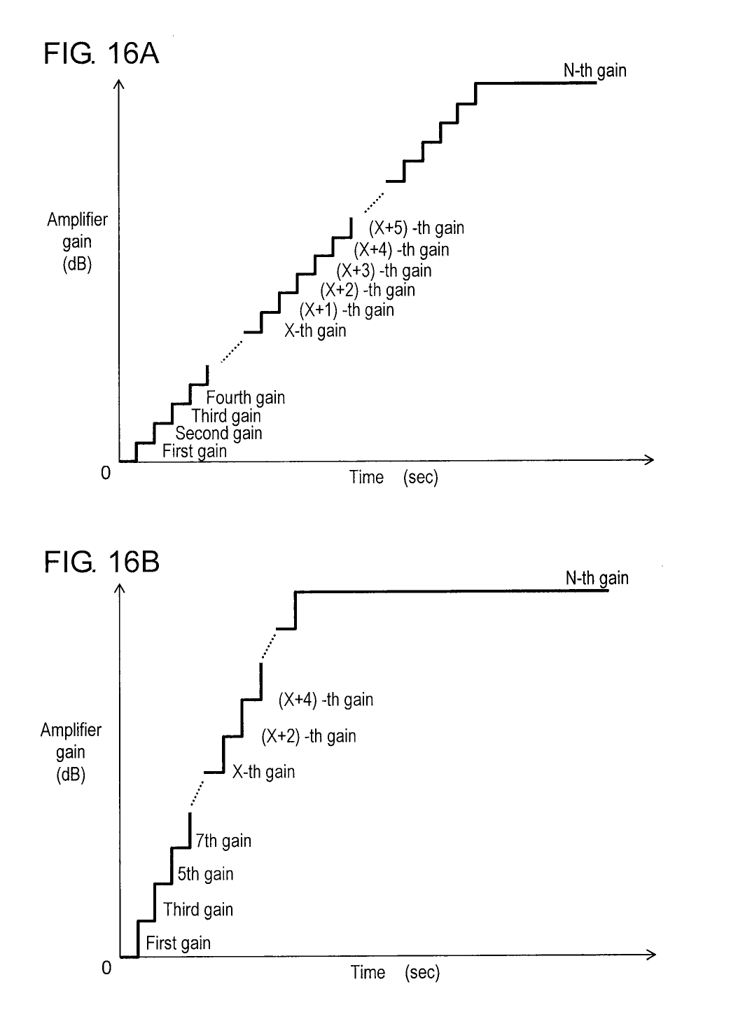

An operation when receiving the analog broadcasting or the digitally modulated signal of step-variable gain amplifier 2 in reception device 401 thus configured is described in detail below with reference to FIG. 16A and FIG. 16B.

FIG. 16A is a chart showing temporal variation in the gain of the step-variable gain amplifier when receiving the analog modulated signal. FIG. 16B is a chart showing temporal variation in the gain of the step-variable gain amplifier when receiving the digitally modulated signal.

In step-variable gain amplifier 2 having the control voltage vs gain characteristics shown in FIG. 2, it is presumed that an initial value of the amplifier gain is a first gain, and a required gain is an N-th gain. When receiving the analog modulated signal, a signal indicating that the received signal is the analog modulated signal is inputted from block controlling unit 405 into controller 404, and controller 404 controls so as to change the number of the gain of step-variable gain amplifier 2 one by one as shown in FIG. 16A. As the analog modulated signal has poor noise tolerance, if the gain variation per unit time of step-variable gain amplifier 2 is large, a noise occurs in a screen displayed in a display unit that displays the demodulated video signal. Accordingly, it is possible to reduce the gain variation per unit time of the step-variable gain amplifier by changing the number of the gain one by one, and to receive the analog broadcasting in a favorable manner.

When receiving the digitally modulated signal, a signal indicating that the received signal is the digitally modulated signal is inputted from block controlling unit 405 into controller 404, and the number of the gain of step-variable gain amplifier 2 is controlled so as to be changed by more than one as shown in FIG. 16B. As the digitally modulated signal has superior noise tolerance compared to the analog modulated signal, it is possible to receive the broadcasting signal in a favorable manner even if the gain step widths of step-variable gain amplifier 2 is increased.

By controlling the number of the gain so as to be changed by more than one, it is possible to shorten the convergence time until the gain of step-variable gain amplifier 2 reaches the predetermined gain. It should be noted that it is not necessarily required to control the number of the gain of step-variable gain amplifier 2 so as to be changed by more than one when receiving the digitally modulated signal.

Further, during the guard interval period when receiving the digital broadcasting, it is possible to control the number of the gain of step-variable gain amplifier 2 so as to be changed by more than one. The guard interval is provided in order to suppress an influence of a delay wave by a multipath, and as the demodulation is performed with ignoring the data of a guard interval portion, it is possible to increase the variation range of the gain during the guard interval period. With this, a convergence time until the gain of step-variable gain amplifier 2 reaches the predetermined gain can be shortened.

Further, in Embodiments 1 to 5 described above, as shown in FIG. 2, FIG. 5 to FIG. 7, and FIG. 9 to FIG. 11, the step-variable gain amplifier has described as being controlled by the gain control voltage (V). However, it is possible to use a step-variable gain amplifier that can be controlled by a digital value representing the gain control voltage.

Although not particularly described, in each embodiment, the components that constitute the device of the present invention are basically connected electrically to each other. Further, although the description is given taking the example of the reception device in the embodiments, the present invention can be applied to a transmission device in addition to the reception device. Specifically, the present invention can be applied to any transmission equipment out of a reception device, a transmission device, and a transceiving device, and it is possible to perform transmission of analog signals and digital signals with superior transmission characteristics that is realized with a low control voltage.

### INDUSTRIAL APPLICABILITY

According to the present invention, there is provided a reception device capable of operating at low control voltage and having favorable reception characteristics, in a reception device capable of receiving an analog modulated signal used for a television set for home use, a mobile telephone, an in-vehicle navigation system, and the like.

### REFERENCE MARKS IN THE DRAWINGS

1 Reception Device
2 Step-Variable Gain Amplifier
3 Controller
4 Video Restoring Means
5 Display Unit
102 Oscillator
103 Mixer
104 BPF
105 Demodulator
106 Signal Quality Detector

1. A reception device comprising:
a step-variable gain amplifier to which an analog modulated signal is inputted and whose gain discretely varies;
a signal quality detector operable to detect a signal quality value of the analog modulated signal; and
a controller operable to control the gain of the step-variable gain amplifier based on the signal quality value detected by the signal quality detector, wherein
the gain of the step-variable gain amplifier varies within N gains from a first gain to an N-th gain (N is an integer no smaller than 3), and
the controller changes a number of the gain one by one when changing the gain of the step-variable gain amplifier.

2. A reception device comprising:
a step-variable gain amplifier to which one of an analog modulated signal and a digitally modulated signal is inputted and whose gain discretely varies;
a signal quality detector operable to detect a signal quality value of the one of the analog modulated signal and the digitally modulated signal; and
a controller operable to control the gain of the step-variable gain amplifier based on the signal quality value detected by the signal quality detector, and to change a gain step width of the step-variable gain amplifier based on a signal to be demodulated out of the analog modulated signal and the digitally modulated signal, wherein
the gain of the step-variable gain amplifier varies within L gains from a first gain to an L-th gain (L is an integer no smaller than 3) when demodulating the analog modulated signal, and varies within M gains from a first gain to an M-th gain (M is an integer no smaller than 3) when demodulating the digitally modulated signal, and
the controller changes a number of the gain one by one when changing the gain of the step-variable gain amplifier.

3. The reception device according to claim 2, wherein
the gain step width when the signal quality value is a first signal quality value is smaller than the gain step width when the signal quality value is a second signal quality value that is superior to the first signal quality value.

4. The reception device according to claim 2, wherein
when the digitally modulated signal is inputted, the controller changes the gain step width of the step-variable gain amplifier based on a modulation method for the inputted signal.

5. A reception device comprising:
a first step-variable gain amplifier to which one of an analog modulated signal and a digitally modulated signal is inputted and whose gain discretely varies;
a second step-variable gain amplifier that is connected to an output side of the first step-variable gain amplifier;
a signal quality detector operable to detect a signal quality value of the one of the analog modulated signal and the digitally modulated signal; and
a controller operable to control the gain of the first step-variable gain amplifier and a gain of the second step-variable gain amplifier based on the signal quality value, wherein
the gain of the first step-variable gain amplifier varies within A gains from a first gain to an A-th gain (A is an integer no smaller than 3),
the gain of the second step-variable gain amplifier varies within “a” gains from a first gain to an a-th gain (“a” is an integer no smaller than 3),
the controller changes a number of the gain one by one when changing the gain of at least one of the first step-variable gain amplifier and the second step-variable gain amplifier, and
the gain step width of the first step-variable gain amplifier is greater than the gain step width of the second step-variable gain amplifier.

6. The reception device according to claim 5, wherein
the gain of the second step-variable gain amplifier is controlled when the signal quality value of the one of the analog modulated signal and the digitally modulated signal is in a first area, the signal quality value being detected by the signal quality detector, and
the gain of the first step-variable gain amplifier is controlled when the signal quality value of the one of the analog modulated signal and the digitally modulated signal is in a second area in which the signal quality value is superior to that in the first area, the signal quality value being detected by the signal quality detector.

7. The reception device according to claim 1, wherein
in channel selection, the controller changes the number of the gain of the step-variable gain amplifier by more than one.

8. The reception device according to claim 1, wherein
in a period in which a synchronous signal of the analog modulated signal is received, the controller changes the number of the gain of the step-variable gain amplifier by more than one.

9. The reception device according to claim 1, wherein
the digitally modulated signal is also inputted into the step-variable gain amplifier, and
the signal quality detector also detects a signal quality value of the digitally modulated signal.

10. The reception device according to claim 9, wherein
in a period in which the analog modulated signal is not received and only the digitally modulated signal is received, the controller changes the number of the gain of the step-variable gain amplifier by more than one.

11. The reception device according to claim 9, wherein
in a guard interval period of the digitally modulated signal, the controller changes the number of the gain of the step-variable gain amplifier by more than one.

12. The reception device according to claim 2, further comprising:
a fading level detector that is connected to an output side of the step-variable gain amplifier and operable to detect a fading level of the digitally modulated signal, wherein
when the digitally modulated signal is inputted, the controller controls the gain step width of the step-variable gain amplifier based on the fading level outputted from the fading level detector.

13. An electronic device comprising:
the reception device according to claim 2;
video restoring means connected to an output side of the reception device; and
a display unit connected to an output side of the video restoring means.

14. The reception device according to claim 2, wherein
in channel selection, the controller changes the number of the gain of the step-variable gain amplifier by more than one.

15. The reception device according to claim 5, wherein
in channel selection, the controller changes the number of the gain of the step-variable gain amplifier by more than one.
